(19) United States
(12) Patent Application Publication
(10) Pub. No.: US 2026/0247907 A1
(43) Pub. Date: Aug. 20, 2026

(54) THIN FILM-BASED SENSOR ARRAY

(71) Applicant: Applied Materials, Inc., Santa Clara, CA (US)

(72) Inventors: Ganapathy Saravanavel, Bangalore (IN); Gokul Ganesan, Bangalore (IN); Nitin Goral, Bangalore (IN); Gokul Velu, Bangalore (IN); Saravanan Chandrabalu, Bangalore (IN); Punyabrahma Panda, Bangalore (IN); Sathishkumar Kummamoorthy, Bangalore (IN)

(73) Assignee: Applied Materials, Inc., Santa Clara, CA (US)

(21) Appl. No.: 19/058,275

(22) Filed: Feb. 20, 2025

(51) Int. Cl. H01L 21/67; G01K 7/02

(52) U.S. Cl. CPC H10P 72/0602; G01K 7/021; G01K 7/028

(57) ABSTRACT

A method and a device are provided to measure temperatures of a semiconductor wafer in a semiconductor chamber. The device is formed by depositing a thin film matrix stack of aluminum thermoelements and zinc oxide thermoelements on a semiconductor wafer, wherein the aluminum thermoelements and the zinc oxide thermoelements form a junction at each intersection of the thin film matrix and each junction generates a thin film thermocouple. A multiplexor and a microprocessor are affixed to the thin film matrix stack to receive a thermoemf signal from each thin film thermocouple. The generated signals from the thin film thermocouples may be communicated wirelessly. The generated signals from the thin film thermocouples may be processed and compared to determine a number of signals that should be communicated from a local group based on available bandwidth.

### FIELD OF THE DISCLOSURE

The embodiments of the present disclosure relate to methods and systems to use temperature sensor arrays, and, in particular, to providing on-wafer temperature monitoring and control in semiconductor device manufacturing.

### BACKGROUND

One processing parameter used by semiconductor device manufactures is the monitoring and controlling of on-wafer temperature. In semiconductor device manufacturing, the environment is harsh inside the chambers, which makes measurements and communication of measurements difficult. In particular, sensor technologies that use batteries are not able to withstand the temperature and vacuum conditions. Additionally, proper control schemes require dense measurement regions across a surface of the wafers. Without the precise and consistent measurements across the surface of the wafer, calibration and diagnostic testing of heating zones across the wafer surface is not possible. Further, conventional attempts to provide thorough temperature sensing across the wafer results in an amount of data that exceeds typical bandwidth capacities of conventional control systems.

There remains a need in the art for processes that provide accurate, consistent, and rugged on-wafer temperature sensors to allow for control of thin films, plasma etching, diffusion, and clean process tools.

### BRIEF SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter. This summary is merely exemplary of the numerous and varied embodiments. Mention of one or more representative features of a given embodiment is likewise exemplary. Such an embodiment can typically exist with or without the feature(s) mentioned; likewise, those features can be applied to other embodiments of the presently disclosed subject matter, whether listed in this summary or not. To avoid excessive repetition, this Summary does not list or suggest all possible combinations of such features.

In one aspect, a method is provided to measure temperatures of a semiconductor wafer in a semiconductor chamber. A device is formed by depositing a thin film matrix stack of aluminum thermoelements and zinc oxide thermoelements on a semiconductor wafer. The aluminum thermoelements and the zinc oxide thermoelements form a junction at each intersection of the thin film matrix and each junction generates a thin film thermocouple. The method includes affixing a multiplexor and a microprocessor to the thin film matrix stack to receive a thermoemf signal from each thin film thermocouple.

In another aspect of the technology, the method includes identifying a data output from each thin film thermocouple of a local group of thin film thermocouples on the thin film matrix, comparing the data output from each of the thin film thermocouples of the local group, and selecting a number of thin film thermocouples of the local group to communicate to a control system based on the comparison. In another aspect, the comparison identifies differences between the data output of each of the thin film thermocouples of the local group. In another aspect, the method includes accessing historical data based on the data output from each of the thin film thermocouples of the local group, training a machine learning algorithm based on the historical data, using the machine learning algorithm to select the number of thin film thermocouples of the local group to communicate to the control system based on the comparison. In another aspect, the method includes using the machine learning algorithm or other comparison algorithm to identify a signal from a thin film thermocouple that is indicative of a failure of the thin film thermocouple.

In another aspect, the control system provides the received data to a graphical user interface. In another aspect, the graphical user interface displays the received data to represent a temperature profile of the semiconductor wafer. In another aspect, the graphical user interface displays a graph of a temperature of one or more of the thin film thermocouples. In another aspect, the zinc oxide thermoelement is deposited on the semiconductor wafer via direct-current reactive magnetron sputtering. In another aspect, the microprocessor communicates data from the thin film thermocouples wirelessly to a control system. In another aspect, the microprocessor communicates the data wirelessly via a Wi-Fi technology or a Bluetooth technology and is an Internet of Things component. In another aspect, the thin film thermocouples operate without an external power source.

In another aspect of the technology, a thin film sensor array is provided that includes a thin film matrix stack of aluminum thermoelements and zinc oxide thermoelements deposited on a semiconductor wafer. The aluminum thermoelements and the zinc oxide thermoelements form a junction at each intersection of the thin film matrix and each junction generates a thin film thermocouple. A multiplexor and a microprocessor is connected to the thin film matrix stack to receive a thermoemf signal from each thin film thermocouple.

In another aspect, the thin film matrix substantially covers a surface of the semiconductor wafer. In another aspect, a signal from each thin film thermocouple is processed by an amplifier. In another aspect, each thin film thermocouple produces the thermoemf signal based on a change in temperature at the junction of the aluminum thermoelement and the zinc oxide thermoelement.

In another aspect, the thin film sensor array is configured to operate in a temperature environment and a vacuum environment present in a semiconductor chamber. In another aspect, a processor converts the thermoemf signal of each junction into a temperature output. In another aspect, the thin film sensor array is powered by the thermoemf signal.

Other technical features may be readily apparent to one skilled in the art from the following figures, descriptions, and claims.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced. The accompanying drawings illustrate exemplary approaches of the disclosure, including the practical application of the principles thereof, as follows:

FIG. 1 illustrates a temperature sensor array connected to a signal processing system of the in accordance with one embodiment.

FIG. 2 illustrates a junction of aluminum and zinc oxide in accordance with one embodiment.

FIG. 3 illustrates a perspective view of a thin film temperature sensor array on a wafer in accordance with one embodiment.

FIG. 4A illustrates a bottom view of a wafer with a thin film sensor array with a mounted electronics component in accordance with one embodiment.

FIG. 4B illustrates a side perspective view of a wafer with a thin film sensor array with a mounted electronics component in accordance with one embodiment.

FIG. 5 is a graph illustrating the repeatability of the thin film temperature sensor and thermoemf response in accordance with one embodiment.

FIG. 6 is a graph illustrating a comparison of Seeback coefficients of TFTC and wired thermocouples in accordance with one embodiment.

FIG. 7 illustrates a process flow of data from a thin film temperature sensor array in accordance with one embodiment.

FIG. 8 is a block flow diagram of a method to measure temperatures of a semiconductor wafer in a semiconductor chamber.

### DETAILED DESCRIPTION

Processes in accordance with the present disclosure will now be described more fully hereinafter with reference to the accompanying drawings, where various embodiments are shown. The processes may be embodied in many different forms and are not to be construed as being limited to the embodiments set forth herein. Instead, these embodiments are provided so the disclosure will be thorough and complete, and will fully convey the scope of the methods to those skilled in the art.

The terminology used herein is for the purpose of describing particular embodiments only and is not intended to be limiting of the presently disclosed subject matter. While the following terms are believed to be well understood by one of ordinary skill in the art, the following definitions are set forth to facilitate explanation of the presently disclosed subject matter.

All technical and scientific terms used herein, unless otherwise defined below, are intended to have the same meaning as commonly understood by one of ordinary skill in the art. References to techniques employed herein are intended to refer to the techniques as commonly understood in the art, including variations on those techniques or substitutions of equivalent techniques that would be apparent to one of skill in the art. While the following terms are believed to be well understood by one of ordinary skill in the art, the following definitions are set forth to facilitate explanation of the presently disclosed subject matter.

In describing the presently disclosed subject matter, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

A thin film-based temperature sensor array is used to monitor the temperature in a matrix across the surface of a wafer. The technologies described herein provide wireless measurements for live temperature monitoring operating in the vacuum and harsh conditions of the chamber. The matrix of sensors provides better accuracy and higher resolution than conventional technologies. The embedding of the matrix in the thin film allows for a weightless and low-cost solution.

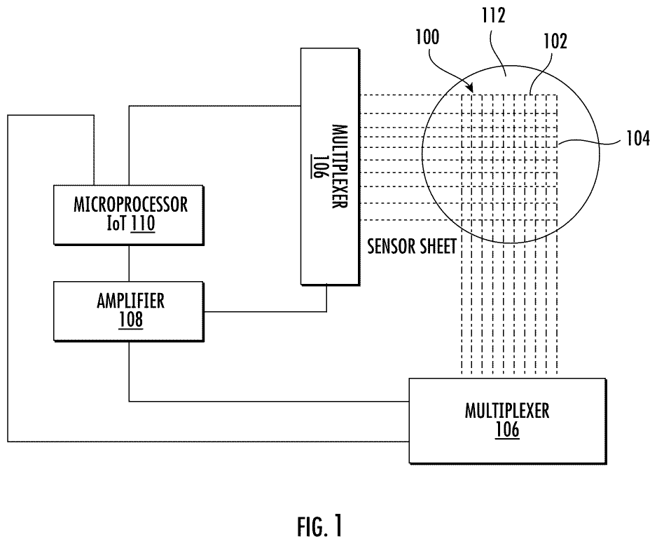

FIG. 1 illustrates a temperature sensor array connected to a signal processing system of the in accordance with one embodiment.

A sensor array 100 is made up of passive matrix stack of aluminum thermoelements 102 and zinc oxide thermoelements 104 deposited in a matrix formation. Together, each junction of the aluminum thermoelement 102 and the zinc oxide thermoelement 104 forms a thermocouple. Thermocouples convert temperature gradients to electrical energy utilizing the Seebeck effect. The output voltage from a thermocouple is proportional to the temperature gradient across its ends and is known as “thermoemf.”

In conventional thermocouples, bulk metals and metal alloys such as platinum, copper, constantan, chromel and alumel are used as thermoelements. However, thin-film thermocouples (TFTCs) have shown improvements over bulk metals and metal alloys due to better linearity and sensitivity. The performance of a thin-film thermocouple is not only sensitive to the physical structure but also to the electrical and thermal properties of the thermoelements. In metal oxides and hybrid alloys, the thermoelectric properties are dependent upon the material composition. Physical vapor deposition (PVD) methods help to synthesize highly pure thin films with controllable deposition rates and nearly stoichiometric compositions. These methods also ensure the film's structural integrity at elevated temperatures. The deposition parameters employed during fabrication influence the thin film's properties.

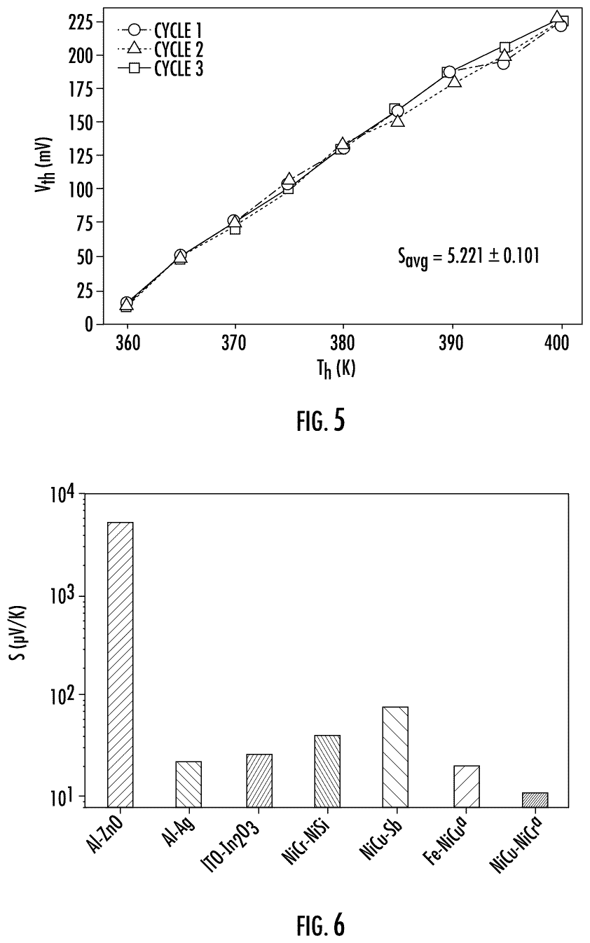

The sensor array 100 has a series of zinc oxide thermoelements 104 illustrated in the vertical lines of the matrix. The aluminum thermoelements 102 are illustrated in the horizontal lines of the matrix. These thermoelements were selected due to a high repeatability of the thermoemf response of Al—ZnO as described with respect to FIG. 5 herein. Al—ZnO also has a high Seeback coefficient relative to other thermoelement combinations as described with respect to FIG. 6 herein.

In ZnO, the lattice imperfections lower the intrinsic thermal conductivity, and the boundary thermal conductivity is a function of the percentage composition of oxygen. The thermal conductivity is also a function of the morphology of ZnO thin films. ZnO, in the form of nanoparticles, shows lowest thermal conductivity when compared to rod, platelet structures. The electrical resistivity and the Seebeck coefficient of ZnO films decrease with temperature. Moreover, aluminum forms an ohmic contact with zinc oxide with ZnO. Al—ZnO forms a contact with a lowest resistance when compared to silver and copper. Therefore, ZnO, owing to its controllable large negative Seebeck coefficient, high electrical conductivity and low thermal conductivity, is used herein as the semiconducting thermoelement.

The matrix stack of aluminum thermoelements 102 and zinc oxide thermoelements 104 in the sensor array 100 are deposited on a wafer 112, such as a round 300 mm semiconductor wafer 112. Any other size, shape, or configuration of wafer 112 may be used, such as a 100, 200, 400 or larger wafer 112. In an example, ZnO is deposited by direct-current reactive magnetron sputtering with pure zinc as the target to create the zinc oxide thermoelement 104. This deposition may be followed by a resistive evaporation of aluminum to create the aluminum thermoelement 102.

The matrix of Al—ZnO is embedded in a grid pattern that may match the shape of the wafer 112. For example, the wafer 112 may be a round wafer 112 of various sizes, such as 100, 200, or 300 millimeters. In another example, the wafer 112 may be square or rectangular. The sensor array 100 may reach each portion of the surface of a wafer 112 or may only cover a portion of the wafer 112. For example, only a square center portion of a round wafer 112 may be measured by the sensor array 100. In another example, the sensor array 100 may have reach near the edges of a round wafer 112 in each direction.

Each intersection of the aluminum thermoelement 102 and the zinc oxide thermoelement 104 creates a junction at which the aluminum thermoelement 102 and the zinc oxide thermoelement 104 are in contact. The contact between the thermoelements at each junction creates a thermocouple that produces a thermoemf signal. The thermoemf signal is created because the two different metals have different conduction rates. The thermoemf created by the junction of the metals changes based on the types of metals used and the temperatures to which the junction is exposed.

By processing this signal at each junction, a matrix array representation of the temperature across the surface of the wafer 112 may be created. As each junction creates an individual output based on temperature, the sensor array 100 provides a detailed view of the heating infrastructure of the chamber or any other heating apparatuses. For example, a user may interrogate one or more junctions to determine a temperature a specific location. A user may observe a temperature profile of the surface of the wafer 112 by observing temperature changes or variations across a section of the junctions.

Generally, thermocouple temperature measurement does not require external power. A voltage signal is generated directly by the temperature changes at the junction. For this reason, the sensor array 100 may be operated in the harsh environments inside a semiconductor chamber without providing a battery or other power source to the sensors. Without batteries, the sensor array 100 is much more robust and rugged and less likely to fail due to extreme temperatures, vacuums, or other harsh conditions. Because of the thermocouple configuration and the ability to operate without batteries, the sensor array 100 operates at a maximum temperature of up to 200 degrees C. In certain configurations, operations in temperatures higher than 200 degrees C. may be achieved, such as 250 degrees C.

Each aluminum thermoelement 102 is electrically connected to a multiplexer 106. Similarly, each zinc oxide thermoelement 104 is electrically connected to a second multiplexer 106. The multiplexers 106 are connected to a microprocessor 110 to process the received signals. An amplifier 108 may be connected to the output of the multiplexers 106 to amplify the signal to increase signal resolution of the signal.

The microprocessor 110 may process the signal locally and/or communicate the signal to a control system. The microprocessor 110 or the control system may create a graphical user interface of the data or perform any other needed functions using the data. For example, a graphical user interface may display to a user a temperature profile of each junction in the sensor array 100. The graphical user interface may be color coded or otherwise designate the temperature in a visual manner. In another example, the microprocessor 110 may use the data to control a series of heaters or other components of a semiconductor chamber. The graphical user interface may convert the data from the sensor array 100 into a graph, such as a bar graph.

The microprocessor 110 may provide the data from the sensor array 100 to a control system or other processor wirelessly. For example, the microprocessor 110 may be an Internet of Things device that communicates wirelessly with a network or other wireless device. The microprocessor 110 may have a component that communicates digital data wirelessly from the microprocessor 110 to a receiving computing device. For example, a control system device may receive the digital communication from the microprocessor 110 and process the received data. The control system may be any type of computing device, such as a computer, a laptop, a mobile device, an automation system for a semiconductor chamber, or any other suitable system or device.

The wireless communication may be based on any suitable wireless communication technology. For example, the communication may be based on a Wi-Fi protocol, Bluetooth, or any other suitable wireless signal. By communicating wirelessly, the wafer 112 housing the sensor array 100 may be placed in a semiconductor chamber or other environment without being connected by a physical electrical connection.

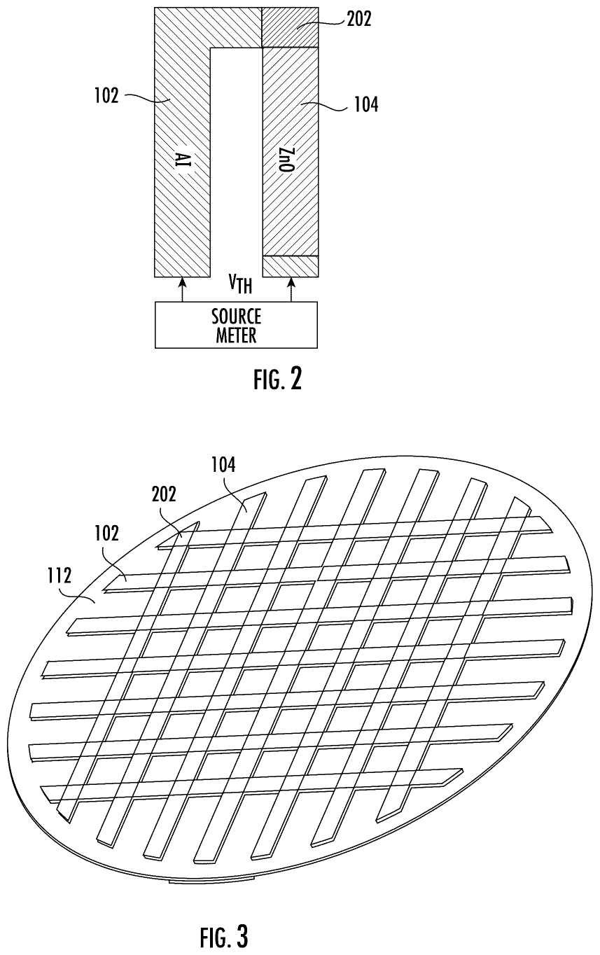

FIG. 2 illustrates a junction of aluminum thermoelement 102 and zinc oxide thermoelement 104 in accordance with one embodiment.

As described with respect to FIG. 1, the aluminum thermoelement 102 and the zinc oxide thermoelement 104 meet at a junction 202. The junction 202 of the thermoelements creates a thermocouple that generates a thermoemf based on temperature changes. The thermoemf may be detected by a meter, such as a voltage meter. The sensor array 100 may be made up of any number of junctions 202, such as 20, 40, 60, 100, 200, or 500.

FIG. 3 illustrates a perspective view of a thin film temperature sensor array 100 on a wafer 112 in accordance with one embodiment.

As described with respect to FIG. 1 and FIG. 2, a series of aluminum thermoelements 102 and a zinc oxide thermoelements 104 are deposited in a thin film on a wafer 112. The wafer 112 is a round semiconductor wafer 112 shown in a perspective view. The crosshatching of the thermoelements creates a series of junctions 202. The seven aluminum thermoelements 102 and the seven zinc oxide thermoelements 104 create a total of 49 individual junctions 202.

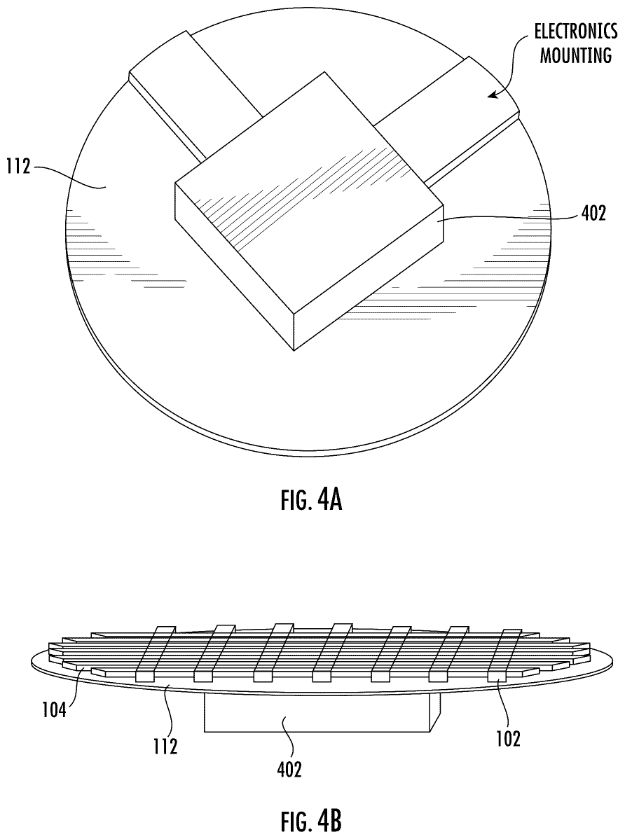

FIG. 4A illustrates a bottom view of a wafer 112 with a thin film sensor array 100 with a mounted electronics component 402 in accordance with one embodiment.

The wafer 112 may be as depicted in FIG. 3. The electronics component 402 may be one or more multiplexers 106 that connect to, and receive a signal from, each aluminum thermoelement 102 and zinc oxide thermoelement 104. In another example, one or more amplifiers 108 are located in the electronics component 402. As described herein, the junctions 202 do not require batteries or power to create or provide a signal to the multiplexers 106.

FIG. 4B illustrates a side perspective view of a wafer with a thin film sensor array with a mounted electronics component in accordance with one embodiment. The wafer 112 may be as depicted in FIG. 3. The electronics component 402 may be as described with respect to FIG. 4A. As depicted, the electronics component 402 is affixed to an underside of the wafer 112.

FIG. 5 is a graph illustrating the repeatability of the thin film temperature sensor and thermoemf response in accordance with one embodiment.

In the graph, three cycles are illustrated for a thin film sensor that is created from a junction 202 of an aluminum thermoelement 102 and a zinc oxide thermoelement 104 as described herein. Each cycle of the temperature was from 360 K to 400 K. The sensitivities of cycle 1, 2 and 3 yielded values of 5.129 mV/K, 5.205 mV/K, and 5.329 mV/K, respectively. Further cycles did not show any significant change in the response and had a minimal deviation of 0.101 mV/K from the average sensitivity. Accordingly, the sensor arrays 100 created using an aluminum thermoelement 102 and a zinc oxide thermoelement 104 are highly repeatable.

FIG. 6 is a graph illustrating a comparison of Seeback coefficients of TFTC and wired thermocouples in accordance with one embodiment.

FIG. 6 illustrates a comparison of the thermoelectric parameters of a junction of Al—ZnO stack and junctions of other pure metal and semiconductor TFTCs and wired thermocouples. The Al—ZnO thermocouple was compared with Al—Ag and with other pure metal and semiconductor pairs in the temperature range of 273 K to 800 K.

As illustrated, the conventional TFTCs and wired thermocouples produced Seebeck coefficients in the range of 10 to 80 μV/K. The Al—ZnO of the current technology produced a Seebeck coefficient in the range of over 5200 μV/K. Therefore, Al—ZnO has better thermoelectric properties when compared to the other TFTCs and wired thermocouples.

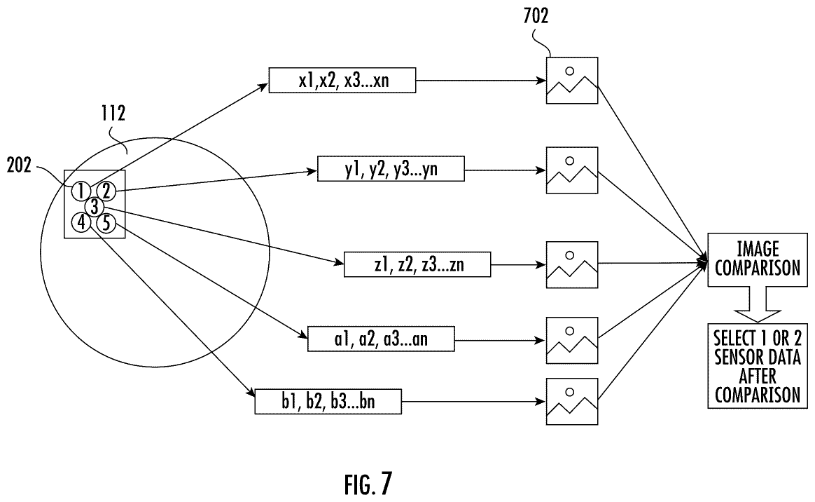

FIG. 7 illustrates a process flow of data from a thin film temperature sensor array 100 in accordance with one embodiment.

In the process of FIG. 7, a wafer 112 has a thin film sensor array 100 as described herein. Five junctions 202 are displayed as junctions 1, 2, 3, 4, and 5. Each junction 202 creates a thermocouple as described herein. The junctions 202 are in a localized section of the wafer 112. Each junction 202, such as junction 1, provides an output of data. For example, the data output for junction 1 is represented as x1, x2, x3, . . . xn.

When each junction 202 is providing data outputs to be read, recorded, displayed, processed, and/or utilized in any suitable manner, the data output may require more bandwidth or processing capacity than a microprocessor 110 or control system can provide. In these situations, a reduction in the size of the data output without a reduction in the quality of the data is desired.

In the process of FIG. 7, the data from one or more junctions 202 is converted to an image. For example, the data from junction 1 is converted to image 702. The data from the other junctions 202 may similarly be converted to images, as illustrated. The conversion to an image may be performed by any suitable computing system or processor. For example, the data may be provided to a control system that operates the semiconductor chamber to be processed. The control system receives the data and converts the data to an image 702 using a conventional conversion algorithm or other software.

The control system compares the images from the junctions 202. In the example, the images, such as image 702, from a localize group of junctions 202 may be compared. The number of junctions 202 in a local group may be determined based on the total number of junctions 202, the size of the wafer 112, the processing capacity of the control system, communication bandwidth available, or any other suitable factors. The geometry of the local group may be determined based on similar criteria. For example, the local group may defined by a square, a circle, a rectangle, or any other shape or configuration.

Based on the results of the image comparison, the control system may select a number of data points to select for use. For example, if the data from each of the five junctions 202 are within a configured range of each other, then the control system may only provide data from a single junction 202, such as junction 1. In an example, if the data from each of the five junctions 202 indicate that a temperature of the wafer 112 is 358K to 359K, then providing five data outputs with similar temperature outputs is redundant and requires additional bandwidth. In another example, the data from two of the junctions 202 indicate a temperature 360K, while three of the junctions 202 indicate 370K. In this example, the control system may select two different outputs to represent the variance in the outputs.

In another example, if the data from the junctions 202 is at such a level that the process of FIG. 7 still does not create enough bandwidth, then the system may stack the images to create videos. The control system may compare the videos based on timestamps to select a number of junctions 202 to process. Similar to the process of FIG. 7, the videos comparison may result in a number of junctions 202 being selected for use, such as one or two junctions 202.

These processes may be used for any other type of sensor data. The process of FIG. 7 may be used to consolidate the data or reduce the bandwidth required for an array or series of pressure sensors, vibration sensors, proximity sensors, or any other suitable type of sensor. For example, a control system may receive data from a series of pressure transducers, process the data, convert the data to images, compare the images, and select a number of pressure transducers to utilize as control data.

In another example, the control system is configured to recognize a failure of a sensor in the sensor array 100. That is, if data coming from a sensor has a spike or other significant change in a short amount of time, then the control system recognizes that the spike is unlikely to be from an actual spike in the temperature and is likely to be a failure of the sensor. The control system may recognize that only a single sensor in the sensor array 100 is registering the spike and ignore the spike. The control system may recognize the spike based on a comparison of the images as described herein with respect to FIG. 7.

For example, data from a sensor 1 is received at time=t₀ and the data=x₀. Data from a sensor 1 is received at time=t₁ and the data=x₁. The control system may auto-correlate the data at t₀, t₁ to determine if the data has changed. If the data has not changed, then the data at t₁ may not be communicated based on bandwidth considerations. If the data at t₁ has changed by a large amount, then the data may be erroneous. For example, a threshold may be configured to identify an erroneous signal, such as a change of 10 degrees K over a 1 second time interval.

In another example, the control system may use a time series forecasting process based on a machine learning algorithm to identify a spike that is likely to be a sensor failure and not an accurate reading. Time series analysis and forecasting utilizes a sequence of data points that are collected and analyzed at evenly-spaced intervals of time, such as at t₀ and t₁. The machine learning algorithm operating on the control system may log historical data and represent the data on a graph with the logged data on the vertical axis and time on the horizontal axis. The machine learning algorithm may learn the normal fluctuations of the temperature for each sensor of the sensor array 100. The machine learning algorithm may learn when a sensor is providing data that is outside of normal operating conditions or fluctuations and identify a likely failure. The control system may elect to ignore the erroneous signal and provide a notification that the sensor is malfunctioning.

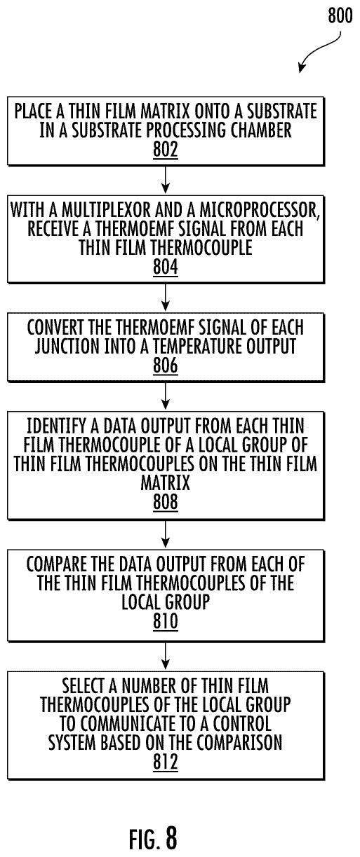

FIG. 8 is a block flow diagram of a method 800 to measure temperatures of a semiconductor wafer 112 in a semiconductor chamber.

In block 802, method 800 places a thin film matrix onto a substrate in a substrate processing chamber. The thin film matrix may be configured as described herein to create a sensor array 100.

In block 804, method 800 receives one or more signals from each thin film thermocouple in the sensor array 100 at a multiplexor 106 and a microprocessor 110. In block 806, method 800 converts the thermoemf signal of each junction into a temperature output.

In block 808, method 800 identifies a data output from each thin film thermocouple of a local group of thin film thermocouples on the thin film matrix of the sensor array 100. In block 810, method 800 compares the data output from each of the thin film thermocouples of the local group. In block 812, method 800 selects a number of thin film thermocouples of the local group to communicate to a control system based on the comparison. The method of blocks 808, 810, and 812 are described in greater detail in at least FIG. 7.

What is claimed is:

1. A thin film sensor array, comprising:
a thin film matrix stack of thermoelements deposited on a semiconductor wafer, wherein the thermoelements form a junction at each intersection of the thin film matrix and each junction generates a thin film thermocouple; and
a multiplexor and a microprocessor connected to the thin film matrix stack to receive a thermoemf signal from each thin film thermocouple.

2. The thin film sensor array of claim 1, wherein the thin film matrix operates at a maximum temperature of 200 degrees C.

3. The thin film sensor array of claim 1, wherein the thermoelements comprise aluminum thermoelements and zinc oxide thermoelements.

4. The thin film sensor array of claim 1, wherein each thin film thermocouple produces the thermoemf signal based on a change in temperature at the junction of the aluminum thermoelement and the zinc oxide thermoelement.

5. The thin film sensor array of claim 4, wherein the thin film sensor array is powered by the thermoemf signal.

6. The thin film sensor array of claim 1, wherein the thin film sensor array is configured to operate in a temperature environment and a vacuum environment in a semiconductor chamber.

7. The thin film sensor array of claim 1, wherein the thin film matrix substantially covers a surface of the semiconductor wafer.

8. A method to measure temperatures of a semiconductor wafer in a semiconductor chamber; comprising:
place a sensor wafer on a substrate in a processing chamber, the sensor wafer comprising a thin film matrix stack of thermoelements deposited on a semiconductor wafer, wherein the thermoelements form a junction at each intersection of the thin film matrix and each junction generates a thin film thermocouple, and an affixed multiplexor and an affixed microprocessor that receives a thermoemf signal from each of the thin film thermocouples; and
measure a temperature of the substrate at each of the thin film thermocouples.

9. The method of claim 8, further comprising converting the thermoemf signal of each junction into a temperature output.

10. The method of claim 8, further comprising:
identifying a data output from each thin film thermocouple of a local group of thin film thermocouples on the thin film matrix;
comparing the data output from each of the thin film thermocouples of the local group; and
selecting a number of thin film thermocouples of the local group to communicate to a control system based on the comparison.

11. The method of claim 10, wherein the comparison identifies differences between the data output of each of the thin film thermocouples of the local group.

12. The method of claim 10, further comprising:
accessing historical data based on the data output from each of the thin film thermocouples of the local group;
training a machine learning algorithm based on the historical data; and
using the machine learning algorithm to select the number of thin film thermocouples of the local group to communicate to the control system based on the comparison.

13. The method of claim 12, further comprising using the machine learning algorithm to identify a signal from a thin film thermocouple that is indicative of a failure of the thin film thermocouple.

14. The method of claim 8, wherein the control system provides the received data to a graphical user interface.

15. The method of claim 14, wherein the graphical user interface displays the received data to represent a temperature profile of the semiconductor wafer.

16. The method of claim 14, wherein the graphical user interface displays a graph of a temperature of one or more of the thin film thermocouples.

17. The method of claim 8, wherein the zinc oxide thermoelement is deposited on the semiconductor wafer via direct-current reactive magnetron sputtering.

18. The method of claim 8, wherein the microprocessor communicates data from the thin film thermocouples wirelessly to a control system.

19. The method of claim 8, wherein the thermoelements comprise aluminum thermoelements and zinc oxide thermoelements.

20. The method of claim 8, wherein the thin film thermocouples operate without an external power source.
